(19) United States
(12) Patent Application Publication
(10) Pub. No.: US 2026/0214896 A1
(43) Pub. Date: Jul. 23, 2026

(54) SEMICONDUCTOR DEVICE AND METHOD FOR MANUFACTURING SEMICONDUCTOR DEVICE

(71) Applicant: Samsung Electronics Co., Ltd., Suwon-si (KR)

(72) Inventors: Taehwan Cha, Suwon-si (KR); Kyung-Tae Jang, Suwon-si (KR); Jaebeom Park, Suwon-si (KR); Dong Young Kim, Suwon-si (KR); Ik Soo Kim, Suwon-si (KR); Hyeju Na, Suwon-si (KR); Hyesong Jeon, Suwon-si (KR); Haeri Mo, Suwon-si (KR)

(21) Appl. No.: 19/269,106

(22) Filed: Jul. 15, 2025

(30) Foreign Application Priority Data
Jan. 23, 2025 (KR) 10-2025-0010006

(51) Int. Cl. H10B 43/27

(52) U.S. Cl. CPC H10B 43/27

(57) ABSTRACT

A method for manufacturing a semiconductor device may include forming a sacrificial pattern in and at least partially filling a first contact hole formed on a stack structure, forming a liner film on the sacrificial pattern, removing the sacrificial pattern in the contact hole after forming the liner film, forming a pre-mask layer on the liner film, and removing a portion of the pre-mask layer to form a mask pattern on the liner film.

### CROSS-REFERENCE TO RELATED APPLICATIONS

This application claims priority to Korean Patent Application No. 10-2025-0010006, filed in the Korean Intellectual Property Office on Jan. 23, 2025, the entire contents of which are hereby incorporated by reference herein.

### FIELD

The present disclosure relates to semiconductor device and method for manufacturing a semiconductor device

### BACKGROUND

There may be demand for semiconductor memory devices capable of storing high-capacity data in an electronic system that requires data storage. Accordingly, ways to increase the data storage capacity of the semiconductor memory devices are being researched. For example, as one method for increasing the data storage capacity of the semiconductor memory device, a semiconductor memory device that includes three-dimensional arrangement of memory cells (instead of two-dimensional arrangement of memory cells) has been proposed.

### SUMMARY

The present disclosure provides a method for manufacturing a semiconductor device in which a uniform mask pattern is formed so that defects in an etching process may be reduced.

According to some embodiments of the present disclosure, by forming a liner film and then forming a mask pattern on the liner film, a height of the mask pattern may be formed uniformly. Accordingly, defects may be reduced in an etching process that uses the mask pattern.

According to some embodiments of the present disclosure, method for manufacturing a semiconductor device may include, forming a sacrificial pattern in and at least partially filling a first contact hole formed on a stack structure, forming a liner film on the sacrificial pattern, removing the sacrificial pattern in the first contact hole after forming the liner film, forming a pre-mask layer on the liner film; and removing a portion of the pre-mask layer to form a mask pattern on the liner film.

According to some embodiments of the present disclosure, a method for manufacturing a semiconductor device may include, forming a stack structure that includes a plurality of mold insulating layers and a plurality of mold sacrificial layers alternately stacked on a substrate, forming a plurality of first contact holes that penetrate a portion of the stack structure, wherein each of the plurality of first contact holes exposes a different mold sacrificial layer among the plurality of mold sacrificial layers, forming a sacrificial pattern in and at least partially filling the plurality of first contact holes, removing a portion of the sacrificial pattern to expose the stack structure, forming a liner film on the stack structure and the sacrificial pattern, removing the sacrificial pattern after forming the liner film thereon, forming a mask pattern on the liner film, and performing an etching process on the plurality of first contact holes using the mask pattern as an etch mask to form a plurality of second contact holes.

According to some embodiments of the present disclosure, a method for manufacturing a semiconductor device may include, forming a stack structure that includes a plurality of mold insulating layers and a plurality of mold sacrificial layers alternately stacked on a substrate, forming a plurality of first contact holes that penetrate a portion of the stack structure, wherein each of the plurality of first contact holes exposes a different mold sacrificial layer among the plurality of mold sacrificial layers, forming a sacrificial pattern in and at least partially filling the plurality of first contact holes, removing a portion of the sacrificial pattern to expose the stack structure, forming a liner film on the stack structure and the sacrificial pattern, removing the sacrificial pattern after forming the liner film thereon, forming a mask pattern on the liner film, and performing an etching process on the plurality of first contact holes using the mask pattern as an etch mask to form a plurality of second contact holes, wherein the liner film covers the plurality of first contact holes, and a thickness of the liner film is in a range of about 10 angstroms to about 30 angstroms.

### BRIEF DESCRIPTION OF THE DRAWINGS

The above and other embodiments and features of the present disclosure will become more apparent by describing in detail example embodiments thereof with reference to the attached drawings, in which:

FIGS. 1 through 9 are figures illustrating a method for manufacturing a semiconductor device according to some embodiments of the present disclosure;

FIG. 10 is a diagram illustrating a method for manufacturing a semiconductor device according to some embodiments of the present disclosure;

FIG. 11 is a flowchart illustrating a method for manufacturing a semiconductor device according to some embodiments of the present disclosure;

FIGS. 12 through 14 are figures illustrating a semiconductor device according to some embodiments of the present disclosure;

FIGS. 15 and 16 are diagrams illustrating a semiconductor device according to some embodiments of the present disclosure. For convenience of explanation, differences in configuration from FIGS. 12-14 will be mainly described;

FIG. 17 is an example block diagram illustrating an electronic system according to some embodiments of the present disclosure;

FIG. 18 is an example perspective view illustrating an electronic system according to some embodiments of the present disclosure;

FIG. 19 is a schematic cross-sectional view taken along line V-V of FIG. 18.

### DETAILED DESCRIPTION OF EMBODIMENTS

In the present disclosure, terms such as first, second, etc. may be used to describe various devices or components, but the devices or components are not limited by these terms. It should be understood that these terms are only used to distinguish one element or component from another element or component. As such, a first element or component mentioned below may be a second element or component within the technical idea of the present disclosure.

Hereinafter, in the specification (and not necessarily in the claims), two directions that are perpendicular or substantially perpendicular to each other among horizontal directions, which are parallel or substantially parallel to an upper surface of each of first, second and third substrates, may be referred to as first and second directions D1 and D2, respectively, and a vertical direction perpendicular or substantially perpendicular to the upper surface of each of the first to third substrates may be referred to as a third direction D3. In example embodiments, the first and second directions D1 and D2 may be perpendicular or substantially perpendicular to each other. Each of the first to third directions D1, D2 and D3 may include not only a direction shown in the drawings but also a direction that is opposite thereto.

The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

The term such as “about” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

Hereinafter, a method for manufacturing a semiconductor device and a semiconductor device according to some embodiments of the present disclosure will be described in detail with reference to the drawings.

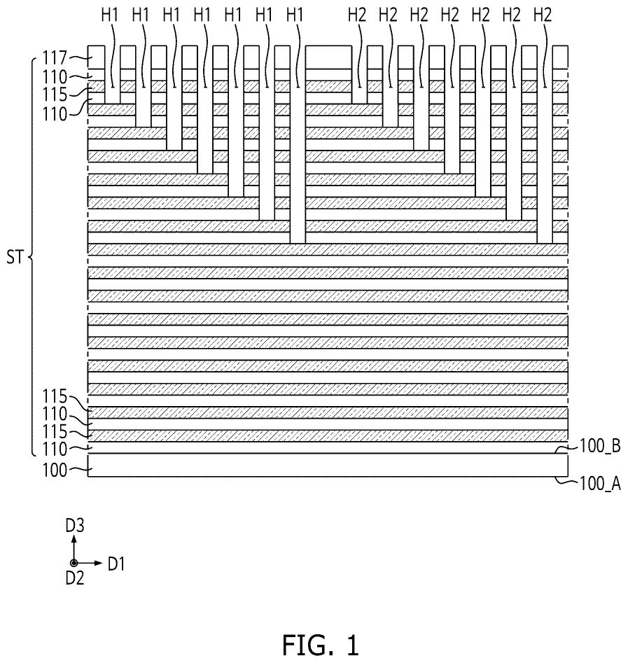

FIGS. 1 through 9 are figures illustrating a method for manufacturing a semiconductor device according to some embodiments of the present disclosure.

Referring to FIG. 1, in the method for manufacturing a semiconductor device according to some embodiments, a stack structure ST and a plurality of contact holes H1 and H2 may be formed on a substrate 100.

Specifically, a stack structure ST may be formed on the substrate 100. The substrate 100 may, for example, include a semiconductor substrate such as a silicon substrate, a germanium substrate, or a silicon-germanium substrate. Alternatively, the substrate 100 may include a Silicon-On-Insulator (SOI) substrate or a Germanium-On-Insulator (GOI) substrate. In some embodiments, the substrate 100 may include poly silicon.

The substrate 100 may include a first surface 100_A and a second surface 100_B opposite the first surface 100_A. The second surface 100_B of the substrate 100 may be a surface on which the stack structure ST is placed. The first surface 100_A of the substrate 100 may be referred to as a back side of the substrate 100. The second surface 100_B of the substrate 100 may be referred to as a front side of the substrate 100.

The stack structure ST may be formed on the second surface 100_B of the substrate 100. The stack structure ST may include a plurality of mold insulating layers 110 and a plurality of mold sacrificial layers 115 that are alternately stacked, and a semiconductor layer 117 disposed at the top thereof. The plurality of mold insulating layers 110 and the plurality of mold sacrificial layers 115 may extend in a direction substantially parallel to the second surface 100_B of the substrate 100. For example, the plurality of mold insulating layers 110 and the plurality of mold sacrificial layers 115 may extend in a first direction D1 and a second direction D2.

The first direction D1 may be a direction intersecting the second direction D2. A third direction D3 may be a direction that intersects each of the first direction D1 and the second direction D2. For example, the first direction D1 and the second direction D2 may be directions substantially parallel to the second surface 100_B of the substrate 100, and the third direction D3 may be a direction substantially perpendicular to the second surface 100_B of the substrate 100.

The semiconductor layer 117 may be disposed at the top of the stack structure ST. The semiconductor layer 117 may be disposed on the topmost one among the plurality of mold insulating layers 110. An upper surface of the semiconductor layer 117 may be an upper surface of the stack structure ST. The semiconductor layer 117 may include, for example, poly silicon.

The mold insulating layer 110 may include an insulating material. The mold insulating layer 110 may, for example, include at least one of a silicon oxide, a silicon nitride, and a silicon oxynitride, although the present disclosure is not limited thereto.

The mold sacrificial layer 115 may include an insulating material. The mold sacrificial layer 115 may, for example, include at least one of a silicon oxide, a silicon nitride, and a silicon oxynitride, although the present disclosure is not limited thereto. In some embodiments, the mold sacrificial layer 115 may include a material that has an etch selectivity relative to the mold insulating layer 110. As an example, the mold insulating layer 110 may include silicon oxide, and the mold sacrificial layer 115 may include silicon nitride.

A plurality of first contact holes H1 and a plurality of second contact holes H2 may be formed on the stack structure ST. The first contact hole H1 may penetrate a portion of the stack structure ST. The first contact hole H1 may penetrate the semiconductor layer 117. The first contact hole H1 may penetrate portions of the plurality of mold insulating layers 110 and portions of the plurality of mold sacrificial layers 115. The first contact hole H1 may extend in the third direction D3. The first contact hole H1 may expose a portion of the mold sacrificial layer 115. For example, a bottom surface of the first contact hole H1 may expose a portion of an upper surface of the mold sacrificial layer 115.

Each of the plurality of first contact holes H1 may be arranged to be spaced apart in the first direction D1. Each of the plurality of first contact holes H1 may be aligned in the first direction D1. A height of each of the plurality of first contact holes H1 may be different. In some embodiments, each of the plurality of first contact holes H1 may expose different mold sacrificial layers 115. For example, each of the plurality of first contact holes H1 may expose an upper surface of a different mold sacrificial layer 115.

The plurality of second contact holes H2 may be arranged spaced apart from the plurality of first contact holes H1 in the first direction D1. The second contact hole H2 may penetrate a portion of the stack structure ST. The second contact hole H2 may penetrate the semiconductor layer 117. The second contact hole H2 may penetrate portions of the plurality of mold insulating layers 110 and portions of the plurality of mold sacrificial layers 115. The second contact hole H2 may extend in the third direction D3. The second contact hole H2 may expose a portion of the mold sacrificial layer 115. For example, a bottom surface of the second contact hole H2 may expose a portion of an upper surface of the mold sacrificial layer 115.

Each of the plurality of second contact holes H2 may be arranged to be spaced apart in the first direction D1. Each of the plurality of second contact holes H2 may be aligned in the first direction D1. A height of each of the plurality of second contact holes H2 may be different. In some embodiments, each of the plurality of second contact holes H2 may expose different mold sacrificial layers 115. For example, each of the plurality of second contact holes H2 may expose an upper surface of a different mold sacrificial layer 115.

In some embodiments, shapes of the plurality of first contact holes H1 may be the same as shapes of the plurality of second contact holes H2. Each of the plurality of first contact holes H1 may correspond to each of the plurality of second contact holes H2. For example, a height of the leftmost first contact hole H1 among the plurality of first contact holes H1 may be the same as a height of the leftmost second contact hole H2 among the plurality of second contact holes H2. However, the present disclosure is not limited thereto. For example, the shapes of the plurality of first contact holes H1 may differ from the shapes of the plurality of second contact holes H2.

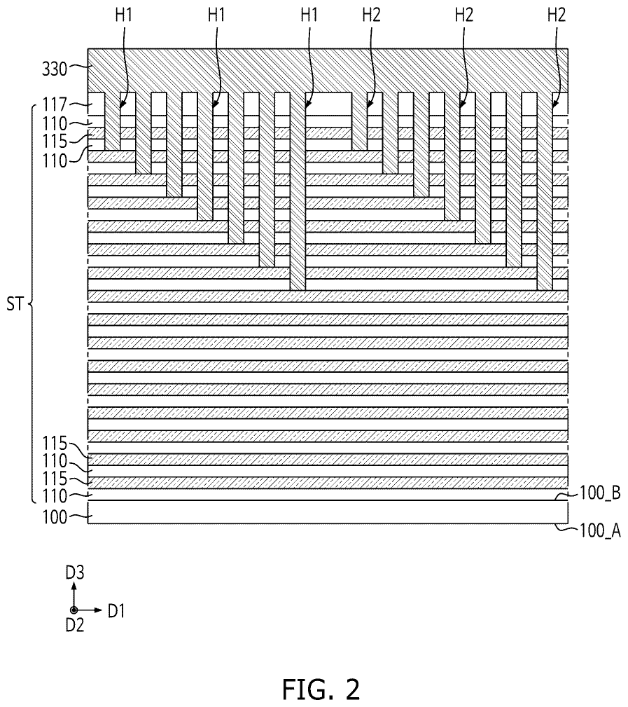

Referring to FIG. 2, a sacrificial pattern 330 may be formed on the plurality of first contact holes H1 and the plurality of second contact holes H2. The sacrificial pattern 330 may fill the plurality of first contact holes H1 and the plurality of second contact holes H2. The sacrificial pattern 330 may be disposed on the stack structure ST. For example, the sacrificial pattern 330 may cover an upper surface of the stack structure ST.

In some embodiments, the sacrificial pattern 330 may include carbon. The sacrificial pattern 330 may be formed by using a plasma-enhanced chemical vapor deposition (PE-CVD) process. For example, the process for forming the sacrificial pattern 330 may use C2H2 as a precursor. However, the present disclosure is not limited thereto. For example, any material containing carbon may be possible as the precursor for forming the sacrificial pattern 330.

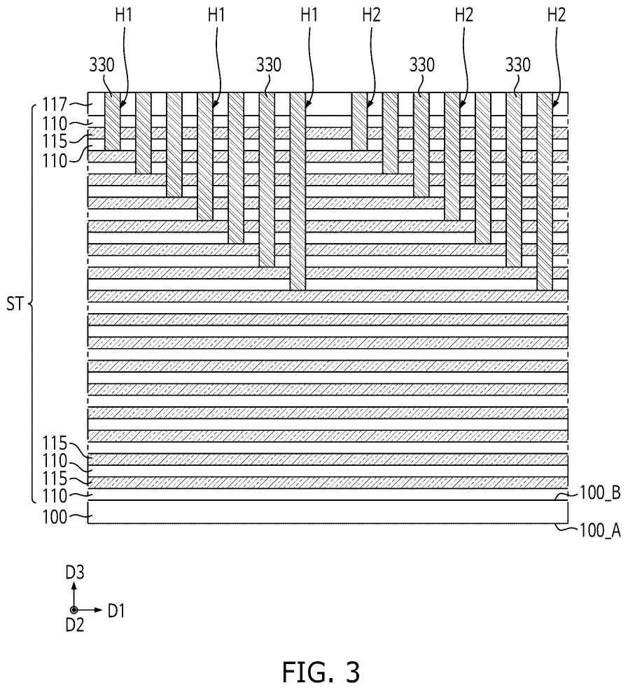

Referring to FIG. 3, a portion of the sacrificial pattern 330 may be removed so that the stack structure is exposed. For example, the sacrificial pattern 330 disposed on an upper surface of the stack structure ST may be removed. As a result, the upper surface of the stack structure ST may be exposed. In addition, the sacrificial pattern 330 disposed in the plurality of first contact holes H1 and the sacrificial pattern 330 disposed in the plurality of second contact holes H2 may be exposed.

The portion of the sacrificial pattern 330 may be removed, for example, by a chemical mechanical polishing (CMP) process, but the present disclosure is not limited thereto.

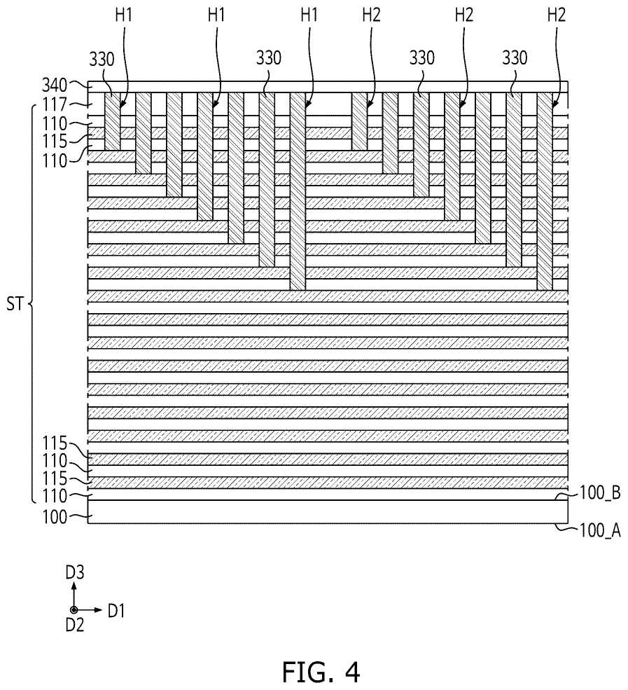

Referring to FIG. 4, a liner film 340 may be formed on the upper surface of the stack structure ST and on the sacrificial pattern 330.

The liner film 340 may extend in the first direction D1 and the second direction D2 and may cover the upper surface of the stack structure ST and upper surfaces of the sacrificial pattern 330. For example, the sacrificial pattern 330 in each of the plurality of first contact holes H1 and the sacrificial pattern 330 in each of the plurality of second contact holes H2 may not be exposed because of the liner film 340. The liner film 340 may include a flat upper surface. The upper surface of the liner film 340 may be substantially parallel to the second surface 100_B of the substrate 100.

In some embodiments, the liner film 340 may be formed conformally. The liner film 340 may be formed, for example, by an atomic layer deposition (ALD) process. However, the present disclosure is not limited thereto.

In some embodiments, the thickness of the liner film 340 may be 30 angstroms or less. For example, the thickness of the liner film 340 may be in a range of 10 angstroms to 30 angstroms. Here, the thickness of the liner film 340 may refer to the thickness in the third direction D3. The liner film 340 may have a porous characteristic. For example, because the material of the liner film 340 and the sufficiently thin thickness of the liner film 340, radical ions may pass through the liner film 340.

In some embodiments, the liner film 340 may include one of a silicon oxide or a silicon nitride. If the liner film 340 includes silicon oxide, the process of forming the liner film 340 may be performed at about 20 to 40 degrees (Celsius). If the liner film 340 includes silicon nitride, the process of forming the liner film 340 may be performed at about 430 to 470 degrees (Celsius). In the present disclosure, references to temperature indicate Celsius (°C.).

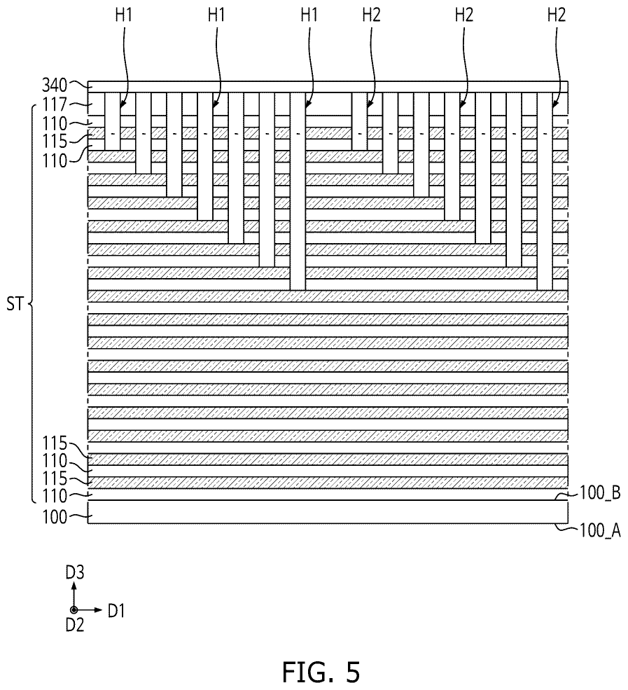

Referring to FIG. 5, the sacrificial pattern 330 (shown in FIG. 4) may be removed. For example, the sacrificial pattern 330 in each of the plurality of first contact holes H1 and the sacrificial pattern 330 in each of the plurality of second contact holes H2 may be completely removed.

In some embodiments, the sacrificial pattern 330 (shown in FIG. 4) may be removed by an ashing process. For example, oxygen O2 plasma may be used in the process of removing the sacrificial pattern 330. Oxygen gas may be converted into a plasma state to form oxygen radical ions, and the oxygen radical ions may react with the sacrificial pattern 330 so as to decompose the sacrificial pattern 330 into CO2 and H2O. The oxygen radical ions may pass through the liner film 340 and react with the sacrificial pattern 330.

In the process of removing the sacrificial pattern 330 (shown in FIG. 4), the liner film 340 may not be removed. As a result, the liner film 340 may cover the plurality of first contact holes H1 and the plurality of second contact holes H2. The interiors of the plurality of first contact holes H1 and the interiors of the plurality of second contact holes H2 may be empty or free of the sacrificial pattern 330.

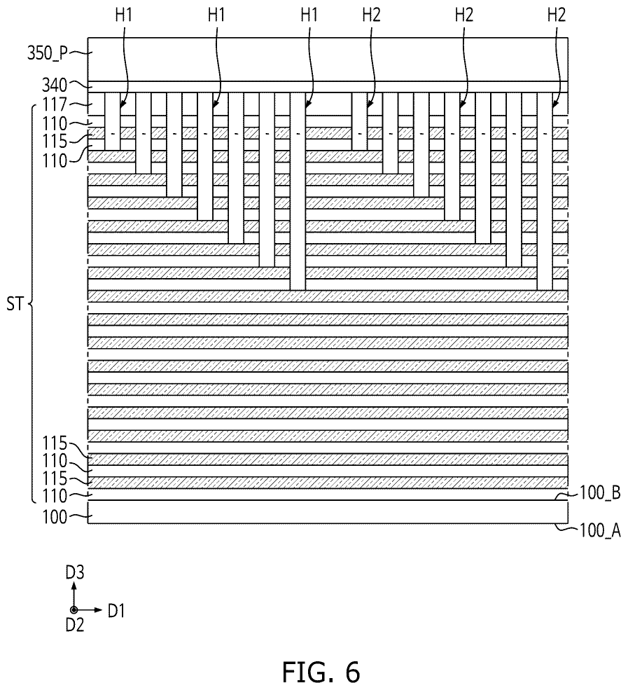

Referring to FIG. 6, a pre-mask layer 350_P may be formed on the liner film 340. The pre-mask layer 350_P may extend in the first direction D1 and the second direction D2. The pre-mask layer 350_P may cover the upper surface of the liner film 340.

In some embodiments, the thickness of the pre-mask layer 350_P may be uniform. For example, the pre-mask layer 350_P may have a flat upper surface. The upper surface of the pre-mask layer 350_P may be substantially parallel to the second surface 100_B of the substrate 100.

The pre-mask layer 350_P may be formed by a spin-on coating process. In some embodiments, the pre-mask layer 350_P may include photoresist (PR). For example, the pre-mask layer 350_P may include either a positive PR or a negative PR.

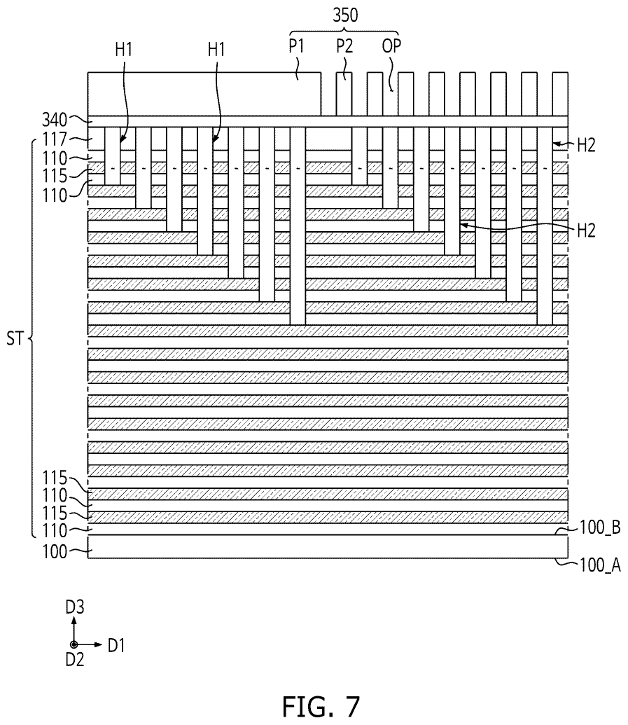

Referring to FIG. 7, a portion of the pre-mask layer 350_P (shown in FIG. 6) may be removed so that a mask pattern 350 is formed. For example, an exposure process and a development process may be performed on the pre-mask layer 350_P so as to pattern the pre-mask layer 350_P.

The mask pattern 350 may include a first portion P1, a second portion P2, and an opening OP. The first portion P1 may extend in the first direction D1. The first portion P1 may cover the upper surface of the liner film 340. The first portion P1 may be disposed on the plurality of first contact holes H1. For example, the first portion P1 may overlap the plurality of first contact holes H1 in the third direction D3. An opening may not be formed in the region corresponding to the first portion P1, unlike the second portion P2.

The opening OP may be disposed in the second portion P2. The second portion P2 may be defined as a portion where the opening OP is disposed. The second portion P2 may surround the opening OP. The second portion P2 may be disposed on the liner film 340. A height of the first portion P1 and a height of the second portion P2 may be the same. Here, “height” may refer to the dimension in the third direction D3.

The plurality of openings OP may be arranged to be spaced apart in the first direction D1. The plurality of openings OP may be aligned in the first direction D1. For example, the distance between each of the plurality of openings OP along the first direction D1 may be the same. The plurality of openings OP may expose a portion of the liner film 340. The plurality of openings OP may overlap the plurality of second contact holes H2 in the third direction D3.

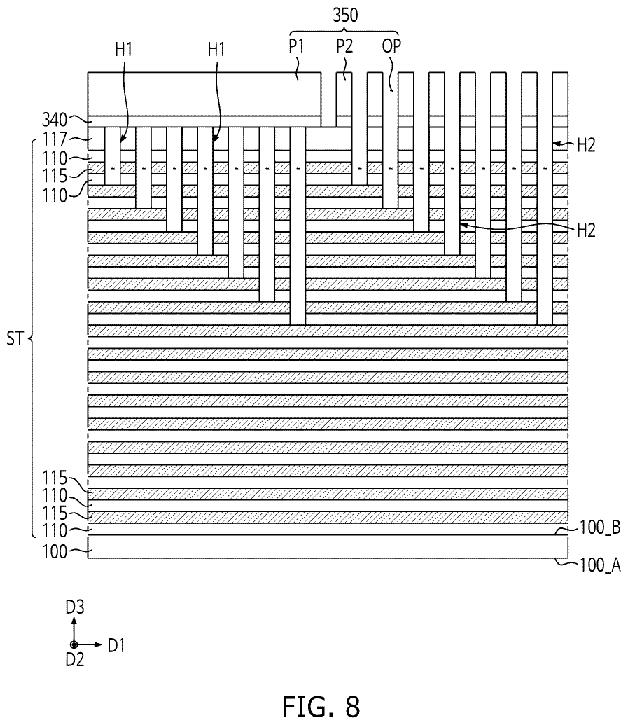

Referring to FIG. 8, a first etching process may be performed on the liner film 340 so that a portion of the liner film 340 is removed.

The openings OP of the mask pattern 350 may expose a portion of the liner film 340. Using the mask pattern 350 as an etch mask, the first etching process may be performed. Through the first etching process, the portion of the liner film 340 exposed by the openings OP may be removed, and the plurality of second contact holes H2 may be exposed.

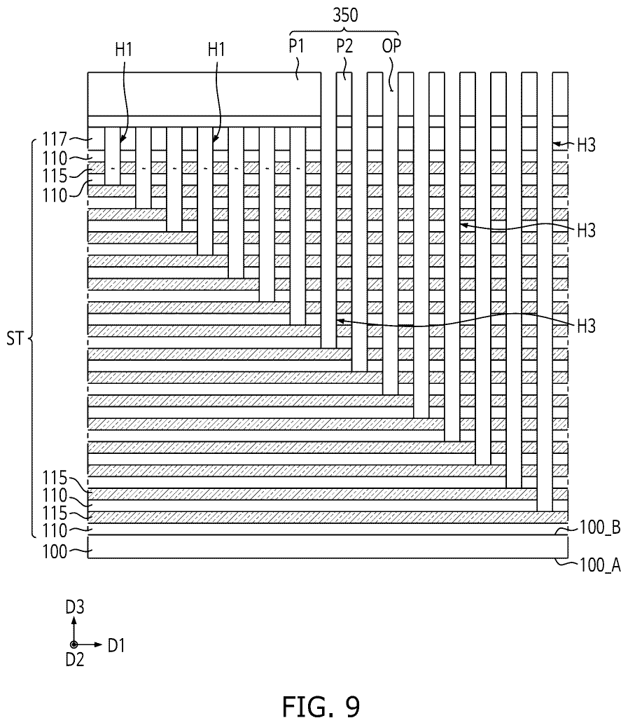

Referring to FIG. 9, a second etching process may be performed on the stack structure ST so that a plurality of third contact holes H3 are formed.

The openings OP of the mask pattern 350 and the liner film 340 may expose the plurality of second contact holes H2 (shown in FIG. 8). Using the mask pattern 350 as an etch mask, the second etching process may be performed. A portion of the stack structure ST exposed by the openings OP may be etched.

Specifically, the second etching process may be performed on the plurality of second contact holes H2 so that the depth of the plurality of second contact holes H2 is increased and the plurality of third contact holes H3 is formed. For example, in the second etching process, eight mold insulating layers 110 and eight mold sacrificial layers 115 may be etched. As a result, the plurality of third contact holes H3 may have a greater depth than the plurality of first contact holes H1. The number of the mold insulating layers 110 and the mold sacrificial layers 115 removed by the second etching process is merely an example, and the present disclosure is not limited thereto.

Each of the plurality of third contact holes H3 may expose different mold sacrificial layers 115. From a cross-sectional perspective, the stack structure ST may have a stepped shape. For example, the plurality of first contact holes H1 and the plurality of third contact holes H3 formed on the stack structure ST may be arranged in a stepped shape. Stated differently, each of the plurality of first contact holes H1 and the plurality of third contact holes H3 may be arranged spaced apart in the first direction D1, and the farther the contact hole is located in the first direction D1, the greater the depth may be.

In forming the mask pattern 350, if the liner film 340 is not present, the height of the mask pattern 350 may be non-uniform. For example, as the depth of the plurality of contact holes H1, H2 increases, the height of the pre-mask layer 350_P may become non-uniform. Where the contact holes H1, H2 are deeper, the height of the pre-mask layer 350_P may be relatively lower, and where the contact holes H1, H2 are shallower, the height of the pre-mask layer 350_P may be relatively higher. As a result, the height of the mask pattern becomes non-uniform, the mask pattern may collapse, and defects may occur in the etching process.

On the other hand, in the method for manufacturing a semiconductor device according to some embodiments of the present disclosure, the sacrificial pattern 330 is formed, and the liner film 340 is formed on the sacrificial pattern 330. Then, by forming the mask pattern 350 on the liner film 340, the height of the mask pattern 350 may be formed uniformly. Accordingly, defects may be reduced in the etching process using the mask pattern 350.

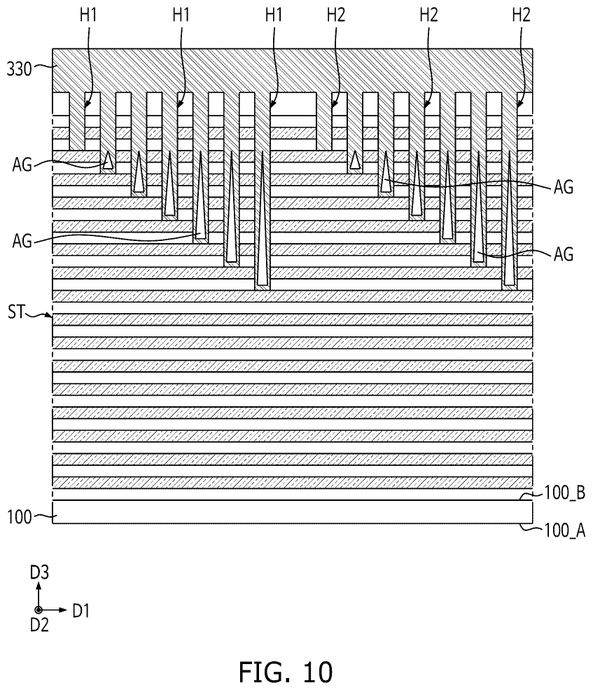

FIG. 10 is a diagram illustrating a method for manufacturing a semiconductor device according to some embodiments of the present disclosure. For convenience of explanation, differences in configuration from FIGS. 1-9 will be mainly described.

Referring to FIG. 10, in the method for manufacturing a semiconductor device according to some embodiments, the sacrificial pattern 330 may include an air gap AG.

The air gap AG may be disposed in the plurality of first contact holes H1 and the plurality of second contact holes H2. The air gap AG may be disposed in at least a portion of each of the plurality of first contact holes H1 and at least a portion of each of the plurality of second contact holes H2. Heights of the air gap AG may differ from each other. The air gap AG may be an empty space. The air gap AG may be formed while the sacrificial pattern 330 fills the interiors of the contact holes H1, H2. Although the air gap AG is illustrated as triangular, the present disclosure is not limited thereto. For example, the air gap AG may have various shapes such as circular or elliptical.

In some embodiments, the topmost height of the air gap AG may be the same among different air gaps AG. For example, the topmost height of the air gap AG formed in the interior of a first contact hole H1 may be the same as the topmost height of the air gap AG formed in the interior of another first contact hole H1 adjacent to that first contact hole H1 in the first direction D1. However, the present disclosure is not limited thereto.

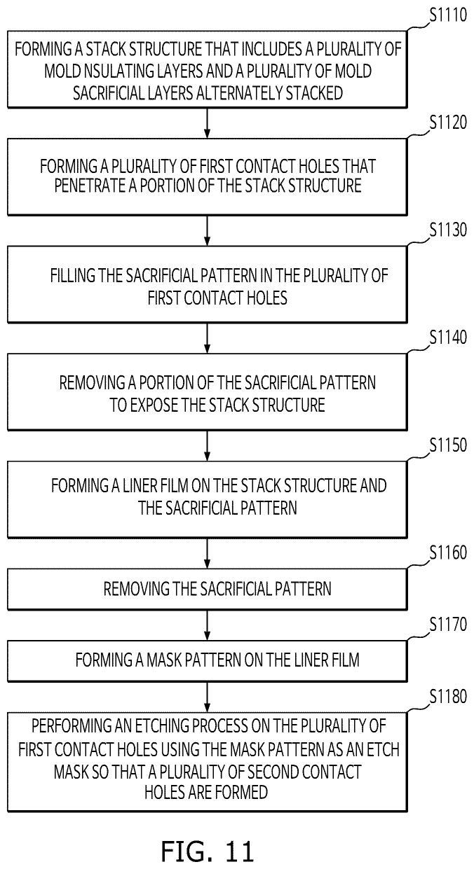

FIG. 11 is a flowchart illustrating a method for manufacturing a semiconductor device according to some embodiments of the present disclosure.

Referring to FIG. 11, the method for manufacturing a semiconductor device according to some embodiments may include forming a stack structure that includes a plurality of mold insulating layers and a plurality of mold sacrificial layers alternately stacked on a substrate (S1110). In some embodiments, a semiconductor layer may be disposed at the top of the stack structure.

Then, a plurality of first contact holes that penetrate a portion of the stack structure may be formed (S1120). Each of the plurality of first contact holes may expose different mold sacrificial layers. Next, the sacrificial pattern may be filled in the plurality of first contact holes (S1130). The sacrificial pattern may fill the plurality of first contact holes and may be disposed on an upper surface of the stack structure. The sacrificial pattern may cover the stack structure. In some embodiments, the sacrificial pattern may include an air gap. The air gap may be disposed in at least a portion of the plurality of first contact holes.

Next, a portion of the sacrificial pattern may be removed so that an upper surface of the stack structure is exposed (S1140). In some embodiments, the portion of the sacrificial pattern may be removed by a chemical mechanical polishing (CMP) process, however, the present disclosure is not limited thereto. Then, a liner film may be formed on the stack structure and on the sacrificial pattern (S1150). The liner film may extend in the first direction. In some embodiments, the thickness of the liner film may be in a range of 10 angstroms to 30 angstroms.

Next, the sacrificial pattern may be removed (S1160). The sacrificial pattern may, for example, be removed by using oxygen plasma, however, the present disclosure is not limited thereto. A mask pattern may be formed on the liner film (S1170). For example, a pre-mask layer may be formed on the liner film, and then the pre-mask layer may be patterned to form the mask pattern. In some embodiments, the mask pattern may include an opening. The opening may overlap the plurality of first contact holes in a direction substantially perpendicular to the first direction.

Then, using the mask pattern as an etch mask, an etching process may be performed on the plurality of first contact holes so that a plurality of second contact holes are formed (S1180). For example, using the mask pattern as an etch mask, a portion of the liner film may be removed, and an etching process may be performed on the plurality of first contact holes. As a result, the plurality of second contact holes may be formed.

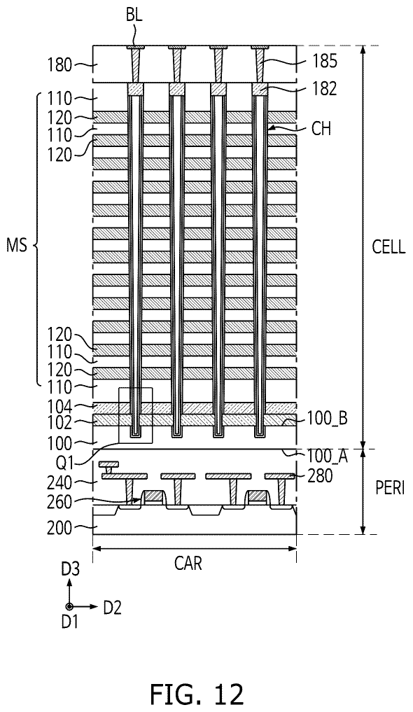

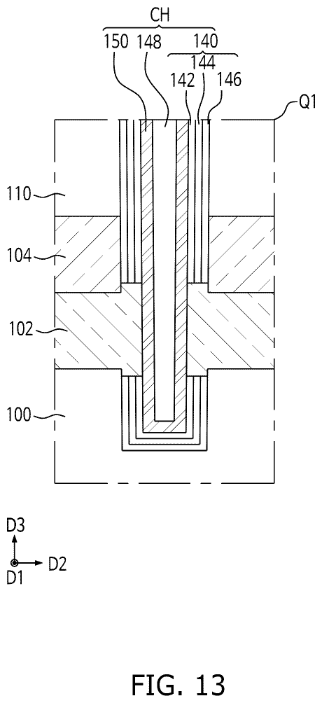

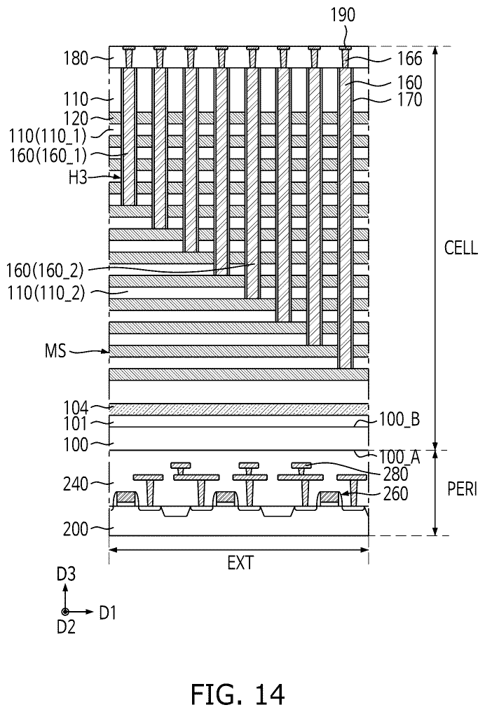

FIGS. 12 through 14 are figures illustrating a semiconductor device according to some embodiments of the present disclosure. FIG. 12 is a cross-sectional view illustrating a cell array region of a semiconductor device according to some embodiments. FIG. 13 is an enlarged view of region Q1 of FIG. 12. FIG. 14 is a cross-sectional view illustrating a connection region of a semiconductor device according to some embodiments.

Referring to FIGS. 12-14, in some embodiments of the present disclosure, the semiconductor device may include a cell structure CELL and a peripheral circuit structure PERI.

The cell structure CELL may include a substrate 100, a mold structure MS, source structures 102 and 104, a channel structure CH, a channel pad 182, a channel contact 185, a bit line BL, a word line contact 160, a word line via 166, and a cell wiring structure 190.

The substrate 100 may, for example, include a semiconductor substrate such as a silicon substrate, a germanium substrate, or a silicon-germanium substrate. Alternatively, the substrate 100 may include a Silicon-On-Insulator substrate or a Germanium-On-Insulator substrate. In some embodiments, the substrate 100 may include poly silicon.

The substrate 100 may include a first surface 100_A and a second surface 100_B opposite the first surface 100_A. The second surface 100_B of the substrate 100 may be a surface on which the mold structure MS and the channel structure CH are disposed. The first surface 100_A of the substrate 100 may be referred to as a back side of the substrate 100. The second surface 100_B of the substrate 100 may be referred to as a front side of the substrate 100.

In the cell array region CAR, the mold structure MS may be disposed on the substrate 100. The mold structure MS may be formed on the second surface 100_B of the substrate 100. The mold structure MS may include a plurality of mold insulating layers 110 and a plurality of gate electrodes 120 that are alternately stacked in the third direction D3. Each of the mold insulating layers 110 and gate electrodes 120 may be a layered structure extending substantially parallel to the second surface 100_B of the substrate 100.

In some embodiments, some of the plurality of gate electrodes 120 may be used as a ground select line GSL and an erase control line ECL of the semiconductor device. For example, among the plurality of gate electrodes 120, a gate electrode 120 adjacent to the source structures 102, 104 may be used as the erase control line ECL. The erase control line ECL may be used as the gate electrode of an erase transistor. The erase transistor may perform an erase operation for a plurality of memory cell transistors by generating gate-induced drain leakage GIDL. A gate electrode 120 adjacent to the erase control line ECL may be provided as the ground select line GSL. However, the present disclosure is not limited thereto. The arrangement and the number of ground select lines GSL may vary. In some embodiments, the gate electrode 120 disposed on an upper portion of the mold structure MS may be provided as a string select line SSL of the semiconductor device.

The gate electrode 120 may include a conductive material, for example, a metal such as tungsten W, cobalt Co, or nickel Ni, or a semiconductor material such as silicon, although the present disclosure is not limited thereto.

The mold insulating layer 110 may include an insulating material. For example, the mold insulating layer 110 may include at least one of a silicon oxide, a silicon nitride, or a silicon oxynitride, although the present disclosure is not limited thereto.

The channel structure CH may be disposed in the cell array region CAR. The channel structure CH may penetrate the mold structure MS. For example, the channel structure CH may penetrate each of the plurality of mold insulating layers 110 and each of the plurality of gate electrodes 120 and cross them. The channel structure CH may be disposed in a channel hole extending in the third direction D3. The channel structure CH may have a pillar shape (e.g., a cylindrical shape) extending in the third direction D3. In some embodiments, a cross-section of the channel structure CH may have inclined side surfaces so that the width becomes narrower closer to the substrate 100. However, the present disclosure is not limited thereto.

The channel structure CH may include an information storage layer 140, a semiconductor pattern 150, and a filling pattern 148.

The semiconductor pattern 150 may extend in the third direction D3 and may penetrate the mold structure MS. Although the semiconductor pattern 150 is illustrated in the shape of a cup, the present disclosure is not limited thereto. The semiconductor pattern 150 may, for example, have a cylindrical shape, a rectangular pillar shape, or a solid pillar shape. The semiconductor pattern 150 may, for example, include various semiconductor materials such as single crystalline silicon, polycrystalline silicon, an organic semiconductor material, or a carbon nanostructure, although the present disclosure is not limited thereto.

The information storage layer 140 may be interposed between the semiconductor pattern 150 and each of the gate electrodes 120. For example, the information storage layer 140 may extend along an outer side surface of the semiconductor pattern 150. The information storage layer 140 may, for example, include at least one of a silicon oxide, a silicon nitride, a silicon oxynitride, or a high-k dielectric material having a higher dielectric constant than silicon oxide. Examples of the high-k dielectric material may include at least one of aluminum oxide, hafnium oxide, lanthanum oxide, tantalum oxide, titanium oxide, lanthanum hafnium oxide, lanthanum aluminum oxide, dysprosium scandium oxide, or a combination thereof.

In some embodiments, the information storage layer 140 may be formed as multiple layers. The information storage layer 140 may include a tunnel insulating layer 142, a charge storage layer 144, and a blocking insulating layer 146, which are successively stacked on the outer side surface of the semiconductor pattern 150.

The tunnel insulating layer 142 may, for example, include silicon oxide or a high-k material (e.g., aluminum oxide Al2O3, hafnium oxide HfO2) having a dielectric constant higher than that of silicon oxide. The charge storage layer 144 may, for example, include silicon nitride. The blocking insulating layer 146 may, for example, include silicon oxide or a high-k material (e.g., aluminum oxide Al2O3, hafnium oxide HfO2) having a dielectric constant higher than that of silicon oxide.

In some embodiments, the channel structure CH may further include the filling pattern 148. The filling pattern 148 may be formed so as to fill the inside of the cup-shaped semiconductor pattern 150. The filling pattern 148 may include an insulating material, for example, silicon oxide, although the present disclosure is not limited thereto.

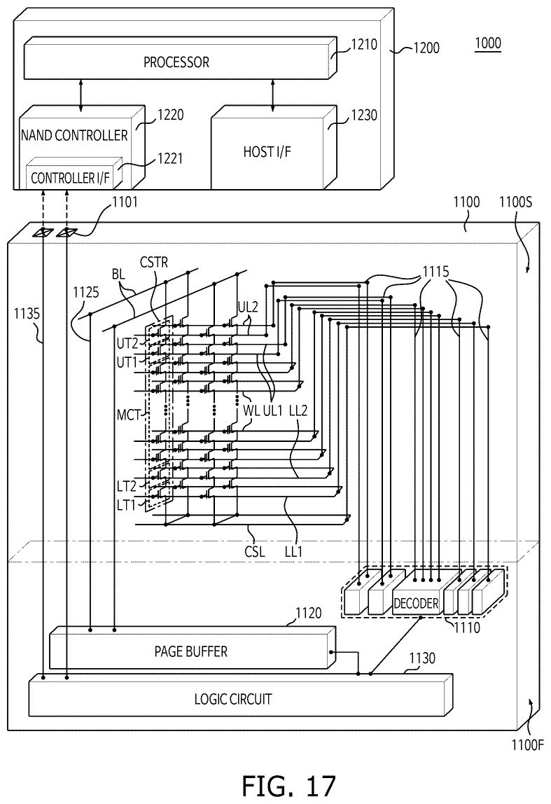

In some embodiments, the source structures 102 and 104 may be formed on the substrate 100. The source structures 102 and 104 may be disposed between the substrate 100 and the mold structure MS. For example, the source structures 102 and 104 may extend along the second surface 100_B of the substrate 100. The source structures 102 and 104 may be formed so as to connect with the semiconductor pattern 150 and/or the information storage layer 140 of the channel structure CH. These source structures 102 and 104 may serve as a common source line (e.g., CSL in FIG. 17) of the semiconductor device. The source structures 102 and 104 may, for example, include a doped polysilicon or a metal, although the present disclosure is not limited thereto.

In some embodiments, the channel structure CH may penetrate the source structures 102 and 104. For example, a lower portion of the channel structure CH may penetrate the source structures 102 and 104 and be disposed within the substrate 100.

In some embodiments, the source structures 102 and 104 may be formed as multiple layers. For example, the source structures 102 and 104 may include a first source layer 102 and a second source layer 104 that are successively stacked on the substrate 100. Each of the first source layer 102 and the second source layer 104 may include polysilicon doped with impurities or undoped polysilicon, although the present disclosure is not limited thereto. The first source layer 102 may be in contact with the semiconductor pattern 150 so as to serve as a common source line (e.g., CSL of FIG. 17) of the semiconductor device. The second source layer 104 may be used as a support layer to prevent collapse or tipping of a mold stack in a replacement process for forming the first source layer 102. In some embodiments, the first source layer 102 may not be disposed on an extension region EXT. An insulating layer 101 may be disposed under the second source layer 104 on the extension region EXT.

Although not shown, a base insulating layer may be interposed between the substrate 100 and the source structures 102 and 104. The base insulating layer may, for example, include at least one of a silicon oxide, a silicon nitride, or a silicon oxynitride, although the present disclosure is not limited thereto.

The channel pad 182 may be disposed on the channel structure CH. The channel pad 182 may be disposed on an upper portion of the channel structure CH and may be electrically connected to the semiconductor pattern 150. A channel contact 185 may be disposed on the channel pad 182. The channel pad 182 may, for example, include doped polysilicon, although the present disclosure is not limited thereto.

The bit line BL may be formed in an upper interlayer insulating layer 180. The bit line BL may extend in the second direction D2 and connect with a plurality of channel structures CH arranged along the second direction D2. For example, within the upper interlayer insulating layer 180, channel contacts 185 that connect with upper portions of each channel structure CH may be formed. The bit line BL may be electrically connected to the channel structures CH through the channel contacts 185.

The word line contact 160 may be disposed on an extension region EXT. The word line contact 160 may extend in the third direction D3 and may connect with a gate electrode 120. For example, the word line contact 160 may penetrate a portion of the mold structure MS so as to connect with the corresponding gate electrode 120. The word line contact 160 may penetrate the mold insulating layer 110 and the gate electrode 120 disposed above the gate electrode 120 to which the word line contact 160 is connected. The word line contact 160 may, for example, include at least one of aluminum Al, tungsten W, cobalt Co, ruthenium Ru, silver Ag, gold Au, manganese Mn, or molybdenum Mo.

A contact spacer 170 may be disposed on a side surface of the word line contact 160. The contact spacer 170 may extend in the third direction D3 along the side surface of the word line contact 160. The contact spacer 170 may surround the word line contact 160. The contact spacer 170 may include an insulating material. For example, the contact spacer 170 may include a silicon oxide-based insulating material.

The word line contact 160 and the contact spacer 170 may be disposed in a third contact hole H3. The third contact hole H3 may be formed by the method for manufacturing a semiconductor device described with reference to FIGS. 1-11.

In some embodiments, the mold insulating layer 110 may include carbon. For example, in the process of forming the third contact hole H3, carbon may diffuse into the mold insulating layer 110.

In some embodiments, a carbon concentration of a first mold insulating layer 110_1 may be lower than a carbon concentration of a second mold insulating layer 110_2. For example, the carbon concentration of the first mold insulating layer 110_1 surrounding a first word line contact 160_1 may be lower than the carbon concentration of the second mold insulating layer 110_2 surrounding a second word line contact 160_2. The height of the first word line contact 160_1 may be smaller than the height of the second word line contact 160_2. In the process of forming the third contact hole H3, a process of forming and removing the sacrificial pattern containing carbon may be repeated. As a result, according to the depth of the third contact hole H3, the carbon concentration of the mold insulating layer 110 forming the sidewall of the third contact hole H3 may vary.

A word line via 166 may be disposed on the word line contact 160. The word line via 166 may be disposed in the upper interlayer insulating layer 180. The word line contact 160 may be electrically connected to the cell wiring structure 190 through the word line via 166.

The peripheral circuit region PERI may include a peripheral circuit substrate 200, a peripheral circuit device 260, and a peripheral circuit wiring structure 280.

The peripheral circuit substrate 200 may be disposed below the substrate 100. For example, an upper surface of the peripheral circuit substrate 200 may face the first surface 100_A of the substrate 100. The peripheral circuit substrate 200 may, for example, include a semiconductor substrate such as a silicon substrate, a germanium substrate, or a silicon-germanium substrate. Alternatively, the peripheral circuit substrate 200 may include an SOI substrate or a GOI substrate.

The peripheral circuit device 260 may be formed on the peripheral circuit substrate 200. The peripheral circuit device 260 may constitute a peripheral circuit that controls an operation of the semiconductor device. For example, the peripheral circuit device 260 may include a logic circuit 1130, a page buffer 1120, or a decoder 1110 of FIG. 17. In the following description, the surface of the peripheral circuit substrate 200 on which the peripheral circuit device 260 is disposed may be referred to as a front side of the peripheral circuit substrate 200. Conversely, a surface of the peripheral circuit substrate 200 opposite the front side may be referred to as a back side of the peripheral circuit substrate 200.

The peripheral circuit device 260 may, for example, include a transistor, although the present disclosure is not limited thereto. For example, the peripheral circuit device 260 may include various active elements such as transistors, as well as various passive elements such as capacitors, resistors, or inductors.

The peripheral circuit wiring structure 280 may be formed on the peripheral circuit device 260. For example, a peripheral circuit wiring insulating layer 240 may be formed on the front side of the peripheral circuit substrate 200, and the peripheral circuit wiring structure 280 may be formed in the peripheral circuit wiring insulating layer 240. The peripheral circuit wiring structure 280 may be electrically connected to the peripheral circuit device 260. The number of layers and arrangement of the peripheral circuit wiring structure 280 as illustrated are merely examples, and the present disclosure is not limited thereto.

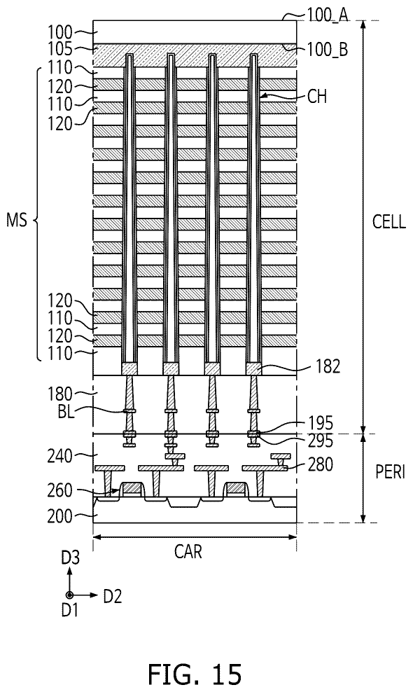

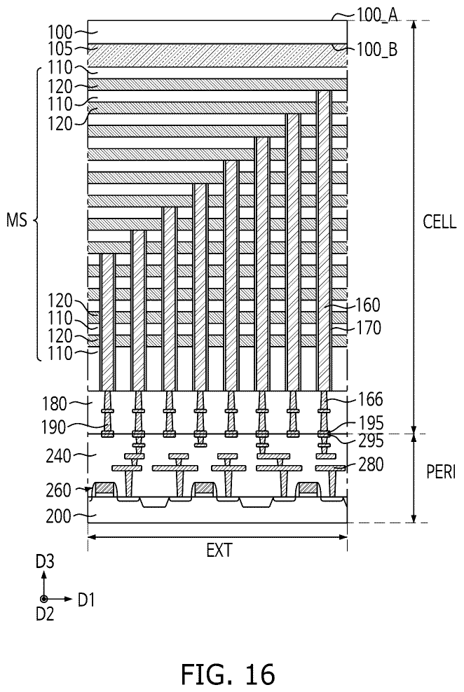

FIGS. 15 and 16 are diagrams illustrating a semiconductor device according to some embodiments of the present disclosure. For convenience of explanation, differences in configuration from FIGS. 12-14 will be mainly described.

Referring to FIGS. 15 and 16, in some embodiments of the present disclosure, the semiconductor device may include a common source plate 105.

The common source plate 105 may be disposed on the second surface 100_B of the substrate 100. The common source plate 105 may be connected with the channel structure CH. For example, the common source plate 105 may be electrically connected to the semiconductor pattern of the channel structure CH. The common source plate 105 may be provided as a common source line (e.g., CSL of FIG. 17) of the semiconductor device. The common source plate 105 may, for example, include doped polysilicon or a metal, although the present disclosure is not limited thereto.

The mold structure MS may be disposed on the common source plate 105. The mold structure MS may include a plurality of mold insulating layers 110 and a plurality of gate electrodes 120 that are alternately stacked in the third direction D3. The gate electrodes 120 may be spaced apart by the mold insulating layers 110 and may be successively stacked on the common source plate 105.

In some embodiments, the cell structure CELL may be stacked on the peripheral circuit structure PERI. The bit line BL of the cell structure CELL may be stacked on the peripheral circuit wiring insulating layer 240.

In some embodiments, the semiconductor device may have a chip-to-chip (C2C) structure. The C2C structure refers to a structure in which an upper chip containing the cell structure CELL is manufactured on a first wafer (for example, the substrate 100), and a lower chip containing the peripheral circuit structure PERI is manufactured on a second wafer (for example, the peripheral circuit substrate 200) different from the first wafer, and then the upper chip and the lower chip are interconnected by a bonding method.

In some embodiments, the bonding method refers to a method of electrically connecting a first bonding metal 195 formed on a topmost metal layer of the upper chip with a second bonding metal 295 formed on a topmost metal layer of the lower chip. For example, if the first bonding metal 195 and the second bonding metal 295 are formed of copper (Cu), the bonding method may be a Cu-Cu bonding method. However, this is merely an example. The first bonding metal 195 and the second bonding metal 295 may of course be formed of other various metals such as aluminum (Al), tungsten (W), or cobalt (Co).

The first bonding metal 195 may be electrically connected to the bit line BL. The second bonding metal 295 may be electrically connected to the peripheral circuit wiring structure 280. By bonding the first bonding metal 195 with the second bonding metal 295, the bit line BL may be connected to the peripheral circuit wiring structure 280. Thus, the bit line BL and/or each of the gate electrodes 120 may be electrically connected to the peripheral circuit device 260.

FIG. 17 is an example block diagram illustrating an electronic system according to some embodiments of the present disclosure.

Referring to FIG. 17, an electronic system 1000 according to example embodiments of the present disclosure may include a semiconductor device 1100 described above with reference to FIGS. 1-16, and a controller 1200 electrically connected to the semiconductor device 1100. The electronic system 1000 may be a storage device including one or more semiconductor devices 1100 or an electronic device (electronic equipment) including the storage device. For example, the electronic system 1000 may be a solid-state drive (SSD), a USB (Universal Serial Bus), a computing system, a medical device, or a communication device, any of which may include one or more semiconductor devices 1100.

The semiconductor device 1100 may be, for example, a NAND flash memory device described above with reference to FIGS. 1-16. The semiconductor device 1100 may include a first structure 1100F and a second structure 1100S on the first structure 1100F. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, word lines WL, first and second gate upper lines UL1, UL2, first and second gate lower lines LL1, LL2, and memory cell strings CSTR between the bit line BL and the common source line CSL.

In the second structure 1100S, each memory cell string CSTR may include lower transistors LT1, LT2 adjacent to the common source line CSL, upper transistors UT1, UT2 adjacent to the bit line BL, and a plurality of memory cell transistors MCT disposed between the lower transistors LT1, LT2 and the upper transistors UT1, UT2. The number of the lower transistors LT1, LT2 and the number of the upper transistors UT1, UT2 may vary in different embodiments.

In example embodiments, the upper transistors UT1, UT2 may include string select transistors, and the lower transistors LT1, LT2 may include ground select transistors. The gate lower lines LL1, LL2 may each be gate electrodes of the lower transistors LT1, LT2. The word lines WL may be gate electrodes of the memory cell transistors MCT, and the gate upper lines UL1, UL2 may each be gate electrodes of the upper transistors UT1, UT2.

The common source line CSL, the first and second gate lower lines LL1, LL2, the word lines WL, and the first and second gate upper lines UL1, UL2 may be electrically connected to the decoder circuit 1110 through first connection wirings 1115 that extend from the first structure 1100F to the second structure 1100S. The bit lines BL may be electrically connected to the page buffer 1120 through second connection wirings 1125 that extend from the first structure 1100F to the second structure 1100S.

In the first structure 1100F, the decoder circuit 1110 and the page buffer 1120 may execute a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 that extends from the first structure 1100F to the second structure 1100S.

The controller 1200 may include a processor 1210, a NAND controller 1220, and a host interface 1230. Depending on embodiments, the electronic system 1000 may include a plurality of semiconductor devices 1100, in which case the controller 1200 may control the plurality of semiconductor devices 1100.

The processor 1210 may control the overall operation of the electronic system 1000 including the controller 1200. The processor 1210 may operate according to predetermined firmware and may access the semiconductor device 1100 by controlling the NAND controller 1220. The NAND controller 1220 may include a NAND interface (or a controller interface) 1221 that processes communications with the semiconductor device 1100. Through the NAND interface 1221, control commands to control the semiconductor device 1100, data to be written to memory cell transistors MCT of the semiconductor device 1100, and data to be read from the memory cell transistors MCT of the semiconductor device 1100 may be transmitted. The host interface 1230 may provide a communication function between the electronic system 1000 and an external host. Upon receiving a control command from the external host through the host interface 1230, the processor 1210 may control the semiconductor device 1100 in response to the control command.

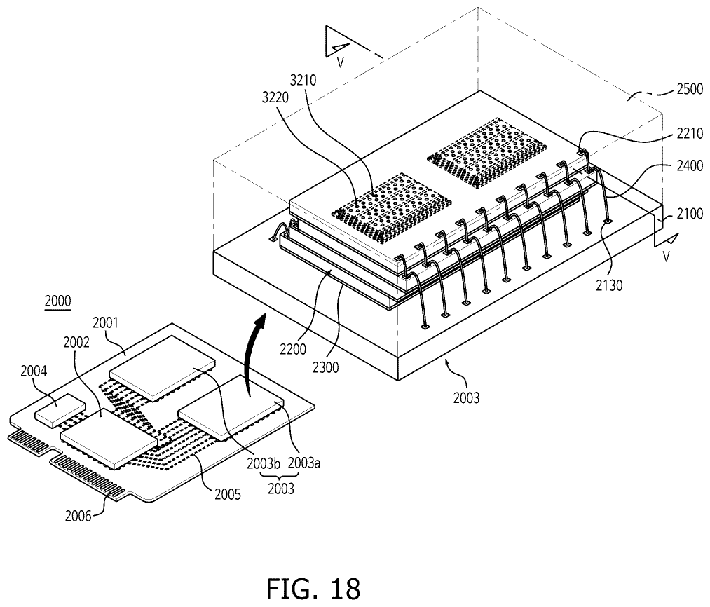

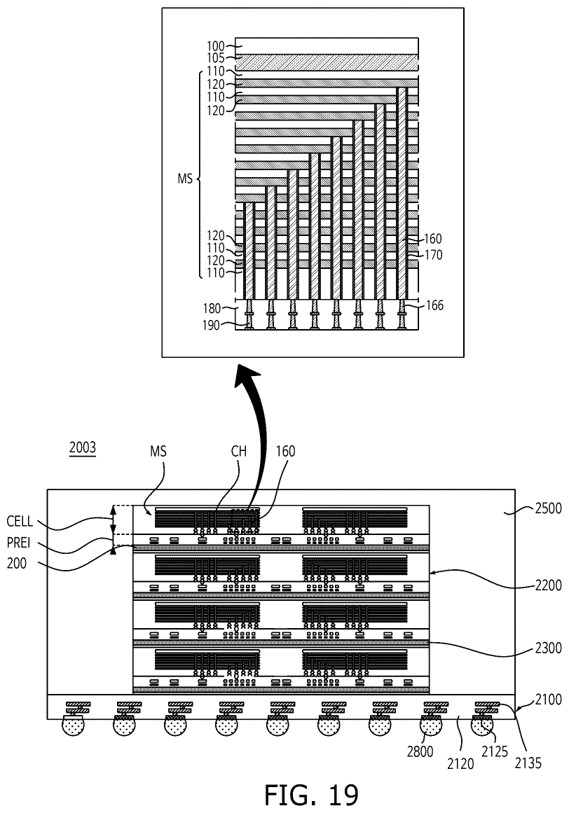

FIG. 18 is an example perspective view illustrating an electronic system according to some embodiments of the present disclosure. FIG. 19 is a schematic cross-sectional view taken along line V-V of FIG. 18.

Referring to FIGS. 18 and 19, an electronic system 2000 according to example embodiments of the present disclosure may include a main substrate 2001, a controller 2002 mounted on the main substrate 2001, one or more semiconductor packages 2003, and a DRAM 2004. The semiconductor packages 2003 and the DRAM 2004 may be interconnected to the controller 2002 by wiring patterns 2005 formed on the main substrate 2001.

The main substrate 2001 may include a connector 2006 that has multiple pins coupled to an external host. The number and arrangement of the multiple pins in the connector 2006 may vary depending on a communication interface between the electronic system 2000 and the external host. In example embodiments, the electronic system 2000 may communicate with the external host through any one of the interfaces such as USB (Universal Serial Bus), PCI-Express (Peripheral Component Interconnect Express), SATA (Serial Advanced Technology Attachment), or M-Phy for UFS (Universal Flash Storage). In example embodiments, the electronic system 2000 may be operated by power supplied from the external host through the connector 2006. The electronic system 2000 may further include a PMIC (Power Management Integrated Circuit) that distributes the power supplied from the external host to the controller 2002 and the semiconductor packages 2003.

The main controller 2002 may write data to or read data from the semiconductor package 2003, and may improve an operating speed of the electronic system 2000.

The DRAM 2004 may be a buffer memory for alleviating a speed difference between the data storage space of the semiconductor package 2003 and the external host. The DRAM 2004 included in the electronic system 2000 may also operate as a kind of cache memory, and may provide a space for temporarily storing data in a control operation for the semiconductor package 2003. When the DRAM 2004 is included in the electronic system 2000, the main controller 2002 may further include a DRAM controller for controlling the DRAM 2004 in addition to the NAND controller for controlling the semiconductor package 2003.

The semiconductor package 2003 may include a first semiconductor package 2003a and a second semiconductor package 2003b that are spaced apart from each other. Each of the first semiconductor package 2003a and the second semiconductor package 2003b may be a semiconductor package that includes a plurality of semiconductor chips 2200. The first semiconductor package 2003a and the second semiconductor package 2003b may each include a package substrate 2100, the semiconductor chips 2200 on the package substrate 2100, adhesive layers 2300 disposed on lower surfaces of each of the semiconductor chips 2200, connection structures 2400 that electrically connect the semiconductor chips 2200 and the package substrate 2100, and a molding layer 2500 covering the semiconductor chips 2200 and the connection structures 2400 on the package substrate 2100.

The package substrate 2100 may be a printed circuit board that includes package upper pads 2130. Each semiconductor chip 2200 may include input/output pads 2210. The input/output pads 2210 may correspond to the input/output pads 1101 of FIG. 17. Each semiconductor chip 2200 may include metal lines 3210 and channel structures 3220. Each semiconductor chip 2200 may include the semiconductor device described above with reference to FIGS. 1-16.

In some embodiments, the connection structures 2400 may be bonding wires that electrically connect the input/output pads 2210 to the package upper pads 2130. Accordingly, in each of the first semiconductor package 2003a and the second semiconductor package 2003b, the semiconductor chips 2200 may be electrically connected to each other by bonding wires, and may be electrically connected to the package upper pads 2130 of the package substrate 2100. In some embodiments, in each of the first semiconductor package 2003a and the second semiconductor package 2003b, the semiconductor chips 2200 may be electrically connected to each other by a connection structure that includes Through Silicon Vias (TSVs) instead of the bonding wires.

In some embodiments, the main controller 2002 and the semiconductor chips 2200 may be included in a single package. In some embodiments, the main controller 2002 and the semiconductor chips 2200 may be mounted on an interposer substrate different and separate from the main substrate 2001, and the main controller 2002 and the semiconductor chips 2200 may be interconnected by wirings formed on the interposer substrate.

In some embodiments, the package substrate 2100 may be a printed circuit board. The package substrate 2100 may include a package substrate body 2120, package upper pads 2130 disposed on an upper surface of the package substrate body 2120, lower pads 2125 disposed on or exposed through a lower surface of the package substrate body 2120, and internal wirings 2135 within the package substrate body 2120 that electrically connect the upper pads 2130 and the lower pads 2125. The upper pads 2130 may be electrically connected with the connection structures 2400. The lower pads 2125 may be connected to the wiring patterns 2005 of the main substrate 2001 of the electronic system 2000 through conductive connection parts 2800, as shown in FIG. 19.

In some embodiments of an electronic system, each of the semiconductor chips 2200 may include the semiconductor device described above with reference to FIGS. 1-18. For example, each of the semiconductor chips 2200 may include the peripheral circuit structure PERI and the cell structure CELL stacked on the peripheral circuit structure PERI. As an example, the cell structure CELL may include the substrate 100, the mold structure MS, the channel structure CH, the word line contact 160, etc. described above with reference to FIGS. 1-16.

Although certain embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

What is claimed is:

1. A method for manufacturing a semiconductor device, the method comprising:
forming a sacrificial pattern in a first contact hole formed on a stack structure, wherein the sacrificial pattern at least partially fills the first contact hole;
forming a liner film on the sacrificial pattern;
removing the sacrificial pattern in the first contact hole, after forming the liner film;
forming a pre-mask layer on the liner film; and
removing a portion of the pre-mask layer to form a mask pattern on the liner film.

2. The method according to claim 1, wherein the liner film extends in a first direction and covers the first contact hole.

3. The method according to claim 1, wherein the mask pattern exposes a portion of the liner film, and the method further comprises:
removing the portion of the liner film that is exposed by the mask pattern.

4. The method according to claim 3, further comprising:
performing an etching process on the first contact hole using the mask pattern as an etch mask to form a second contact hole that extends into the stack structure to a greater depth than the first contact hole.

5. The method according to claim 1, wherein the sacrificial pattern comprises carbon, and wherein the removing of the sacrificial pattern comprises a plasma process.

6. The method according to claim 1, wherein a thickness of the liner film is in a range of about 10 angstroms to about 30 angstroms.

7. The method according to claim 1, wherein the forming of the liner film comprises an atomic layer deposition (ALD) process.

8. The method according to claim 1, wherein the liner film comprises one of silicon oxide or silicon nitride, and wherein the liner film has a porous characteristic.

9. The method according to claim 1, wherein the sacrificial pattern comprises an air gap in the first contact hole.

10. The method according to claim 1, further comprising:
before forming the liner film, removing a portion of the sacrificial pattern to expose an upper surface of the stack structure,
wherein the forming of the liner film comprises forming the liner film on the upper surface of the stack structure.

11. A method for manufacturing a semiconductor device, the method comprising:
forming a stack structure that comprises a plurality of mold insulating layers and a plurality of mold sacrificial layers alternately stacked on a substrate;
forming a plurality of first contact holes that penetrate a portion of the stack structure, wherein each of the plurality of first contact holes exposes a different mold sacrificial layer among the plurality of mold sacrificial layers;
forming a sacrificial pattern in the plurality of first contact holes, wherein the sacrificial pattern at least partially fills the plurality of first contact holes;
removing a portion of the sacrificial pattern to expose the stack structure;
forming a liner film on the stack structure and the sacrificial pattern;
removing the sacrificial pattern after forming the liner film thereon;
forming a mask pattern on the liner film; and
performing an etching process on the plurality of first contact holes using the mask pattern as an etch mask to form a plurality of second contact holes.

12. The method according to claim 11, wherein each of the plurality of second contact holes exposes a different mold sacrificial layer among the plurality of mold sacrificial layers.

13. The method according to claim 11, wherein the sacrificial pattern comprises an air gap in at least a portion of the plurality of first contact holes.

14. The method according to claim 11, wherein the liner film extends in a first direction and covers the plurality of first contact holes.

15. The method according to claim 11, further comprising:
forming a plurality of word line contacts, wherein each of the plurality of word line contacts is formed in a respective second contact hole among the plurality of second contact holes.

16. The method according to claim 11, wherein the stack structure further comprises a semiconductor layer at a portion of the stack structure farthest from the substrate.

17. The method according to claim 11, wherein the mask pattern comprises a plurality of openings aligned in a first direction, and the plurality of openings overlap the plurality of first contact holes in a second direction intersecting the first direction.

18. The method according to claim 11, wherein the mask pattern comprises a first portion extending in a first direction and a second portion comprising a plurality of openings aligned in the first direction.

19. The method according to claim 11, wherein the plurality of second contact holes comprises a first sub-contact hole and a second sub-contact hole spaced apart from the first sub-contact hole in a first direction,
the first sub-contact hole exposes a first mold insulating layer among the plurality of mold insulating layers,
the second sub-contact hole exposes a second mold insulating layer among the plurality of mold insulating layers that is below the first mold insulating layer, and
a first carbon concentration of the first mold insulating layer is lower than a second carbon concentration of the second mold insulating layer.

20. A method for manufacturing a semiconductor device, the method comprising:
forming a stack structure that comprises a plurality of mold insulating layers and a plurality of mold sacrificial layers alternately stacked on a substrate;
forming a plurality of first contact holes that penetrate a portion of the stack structure, wherein each of the plurality of first contact holes exposes a different mold sacrificial layer among the plurality of mold sacrificial layers;
forming a sacrificial pattern in the plurality of first contact holes, wherein the sacrificial pattern at least partially fills the plurality of first contact holes;
removing a portion of the sacrificial pattern to expose the stack structure;
forming a liner film on the stack structure and the sacrificial pattern;
removing the sacrificial pattern after forming the liner film thereon;
forming a mask pattern on the liner film; and
performing an etching process on the plurality of first contact holes using the mask pattern as an etch mask to form a plurality of second contact holes,
wherein the liner film covers the plurality of first contact holes, and
wherein a thickness of the liner film is in a range of about 10 angstroms to about 30 angstroms.
